(19) United States
(12) Patent Application Publication
(10) Pub. No.: US 2013/0308284 A1
(43) Pub. Date: Nov. 21, 2013

(54) ELECTRONIC DEVICE WITH PRINTED CIRCUIT BOARD

(71) Applicants: Hong Fu Jin Precision Industry (ShenZhen) Co., Ltd., (US); HON HAI PRECISION INDUSTRY CO., LTD., New Taipei (TW)

(72) Inventor: GUANG-FENG OU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/740,166

(22) Filed: Jan. 12, 2013

(30) Foreign Application Priority Data
May 15, 2012 (CN) 201210149661.1

(51) Int. Cl. H05K 9/00

(52) U.S. Cl. CPC H05K 9/0064
USPC 361/752; 174/388

(57) ABSTRACT

An electronic device includes a chassis and a printed circuit board secured to the chassis. The printed circuit board includes a base plate, a bottom layer located above the base plate, and a ground plane located above the bottom layer. The bottom layer is located between the base plate and the ground plane; a plurality of copper pins are electrically connected to the base plate and the ground plane through the bottom layer; and the plurality of copper pins, the base plate, and the ground plane cooperatively define a faraday cage and shield the bottom layer from electromagnetic interference.

### BACKGROUND

1. Technical Field

The present disclosure relates to electronic devices, more particularly to an electronic device with a printed circuit board.

2. Description of Related Art

Printed circuit boards are provided in many different types of electronic devices. When the printed circuit boards are working, electromagnetic interference generated from electronic components in the electronic device may affect signals during transmission of the signals within printed circuit boards.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of a printed circuit board in accordance with an embodiment.

FIG. 2 is a cross-sectional view of the printed circuit board of FIG. 1, taken along a line II-II of FIG. 1.

FIG. 3 is a schematic view of an assembly of a printed circuit board and a chassis in accordance with an embodiment.

FIG. 4 is a cross-sectional view of the assembly of the printed circuit board and the chassis, taken along a line IV-IV of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

A printed circuit board is used to mechanically support and electrically connect electronic components using conductive pathways, tracks or signal traces etched from copper sheets laminated onto a non-conductive substrate. It is also referred to as printed wiring board or etched wiring board. Printed circuit boards are used in virtually all electronic devices.

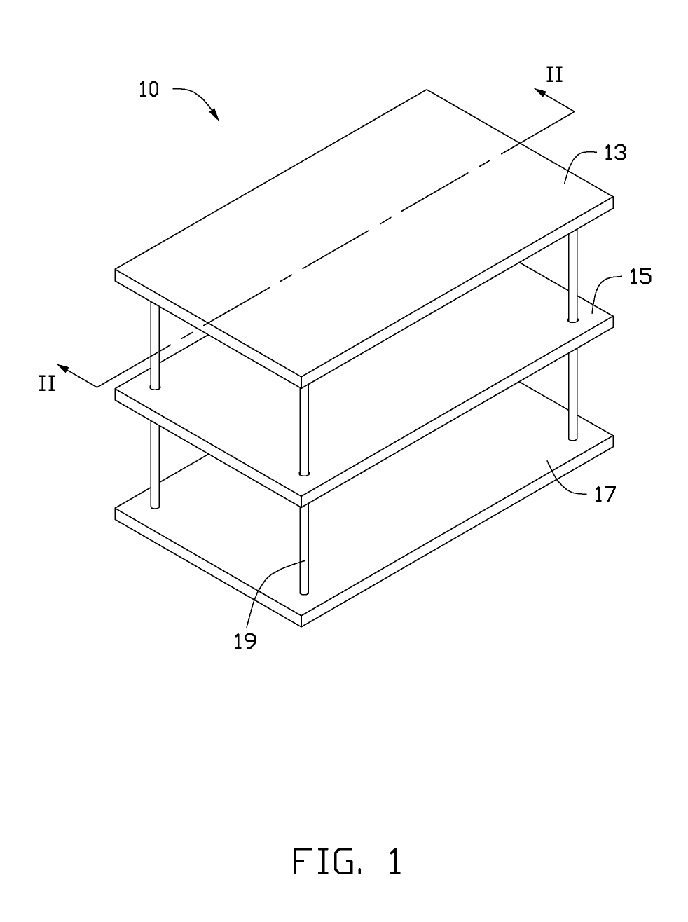

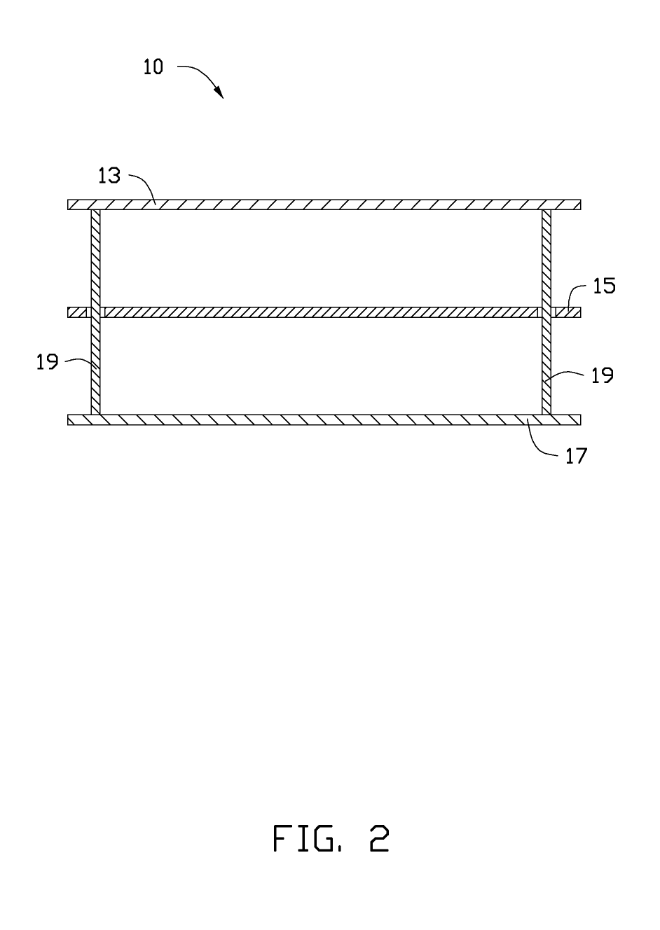

FIGS. 1-2 illustrate a printed circuit board 10 of an embodiment. The printed circuit board 10 comprises a base plate 17, a bottom layer 15, and a ground plane 13. The bottom layer 15 is located above the base plate 17. The ground plane 13 is located on the bottom layer 15. The bottom layer 15 is located between the base plate 17 and the ground plane 13. A plurality of copper pins 19 passes through the bottom layer 15 and is electrically connected to the base plate 17 and the ground plane 13. The plurality of copper pins 19, the base plate 17, and the ground plane 13 together define a faraday cage to shield the bottom layer 15 from electromagnetic interference.

The base plate 17 is made of metal. All of the copper pins 19 are parallel to each other, and a distance defined between every adjacent two of the plurality of copper pins 19 is about 1.5 mm. An area on the base plate 17 or the ground plane 13 outlined by the plurality of the copper pins 19 is substantially rectangular. The bottom layer 15 is insulated from the base plate 17 by insulation material. The insulation material can prevent the printed circuit board 10 from being damaged.

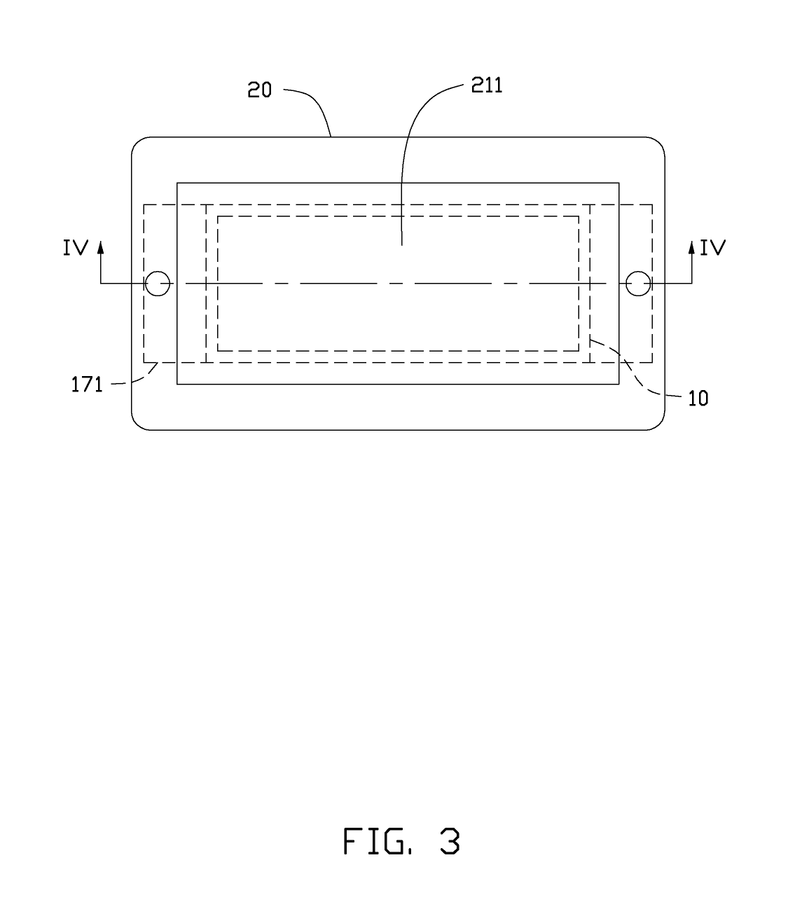

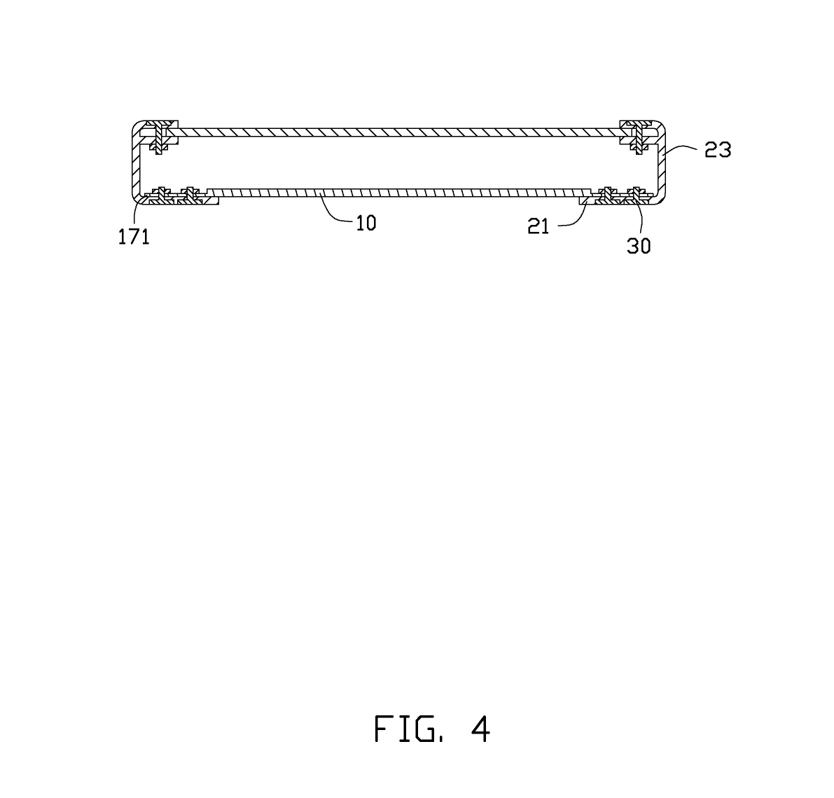

Referring to FIGS. 3-4, the printed circuit board 10 can be secured to a chassis 20 of an electronic device. The base plate 17 comprises two opposite mounting portions 171, which extend out of the bottom layers 15 and the ground plane 13. A plurality of mounting holes (not labeled) is defined in each of the two opposite mounting portions 171, only one mounting hole of each of the two opposite mounting portions 171 is shown in FIG. 3. The chassis 20 comprises a bottom wall 21 and two sidewalls 23 located on opposite sides of the bottom wall 21. In an embodiment, the two sidewalls 23 are substantially parallel to each other and perpendicular to the bottom wall 21. The bottom wall 21 defines a plurality of securing holes (not shown) and a through opening 211. A plurality of fasteners 30, such as screws, is fixed in the plurality of securing holes and the plurality of the mounting holes to secure the printed circuit board 10 to the bottom wall 21 of the chassis 20. The printed circuit board 10 covers the through opening 211. A shape of the through opening 211 has a substantially same shape as a shape of the printed circuit board 10, and an area of the through opening 211 is slightly smaller than an area of the printed circuit board 10. In an embodiment, the shape of the through opening 211 and the printed circuit board 10 is rectangular. When the printed circuit board 10 is working, heat generated from the printed circuit board 10 is dissipated out of the chassis 20 via the through opening 211.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A printed circuit board comprising:
a base plate;
a bottom layer located above the base plate; and
a ground plane located above the bottom layer;
wherein the a plurality of copper pins are electrically connected to the base plate and the ground plane through the bottom layer; and the plurality of copper pins, the base plate, and the ground plane cooperatively define a faraday cage and shield the bottom layer from electromagnetic interference.

2. The printed circuit board of claim 1, wherein the base plate is made of metal.

3. The printed circuit board of claim 1, wherein a distance between every adjacent two of the plurality of copper pins is about 1.5 mm.

4. The printed circuit board of claim 1, wherein an area on the base plate or the ground plane outlined by the plurality of the copper pins is substantially rectangle.

5. The printed circuit board of claim 1, wherein the bottom layer is insulated from the base plate by insulation media.

6. An electronic device comprising:
a chassis; and
a printed circuit board secured to the chassis; the printed circuit board comprising a base plate, a bottom layer located above the base plate, and a ground plane located on the bottom layer;
wherein the bottom layer is located between the base plate and the ground plane; a plurality copper pins passes through the bottom layer and are electrically connected to the base plate and the ground plane; and the plurality of copper pins, the base plate, and the ground plane cooperatively define a faraday cage and shield the bottom layer from electromagnetic interference.

7. The electronic device of claim 6, wherein the base plate is made of metal.

8. The electronic device of claim 6, wherein a distance between every adjacent two of the plurality of copper pins is about 1.5 mm.

9. The electronic device of claim 6, wherein an area on the base plate or the ground plane outlined by the plurality of the copper pins is substantially rectangle.

10. The electronic device of claim 6, wherein the bottom layer is insulated from the base plate by insulation media.

11. The electronic device of claim 6, wherein the chassis comprises a bottom wall, the base plate comprises two opposite mounting portions, and each of the two opposite mounting portions is secured to the bottom wall.

12. The electronic device of claim 11, wherein the bottom wall defines a through opening, and the through opening is cover by the printed circuit board.

13. The electronic device of claim 12, wherein a shape of the through opening has a substantially same shape as a shape of the printed circuit board, and an area of the through opening is slightly smaller than an area of the printed circuit board.
